(19) United States
(12) Patent Application Publication
(10) Pub. No.: US 2026/0082912 A1
(43) Pub. Date: Mar. 19, 2026

(54) SEMICONDUCTOR STRUCTURES AND MANUFACTURING METHOD OF THE SAME

(71) Applicant: Taiwan Semiconductor Manufacturing Company, Ltd., Hsinchu (TW)

(72) Inventors: Kuo-Chiang Ting, Hsinchu City (TW); Sung-Feng Yeh, Taipei City (TW); Ta-Hao Sung, Yilan County (TW); Jia-Kuen Wang, Hsinchu City (TW)

(73) Assignee: Taiwan Semiconductor Manufacturing Company, Ltd., Hsinchu (TW)

(21) Appl. No.: 18/890,654

(22) Filed: Sep. 19, 2024

(51) Int. Cl. H01L 23/473

(52) U.S. Cl. CPC H10W 40/47

(57) ABSTRACT

A structure including a semiconductor component, a cooling structure disposed on the semiconductor component and a capping layer disposed between the cooling structure and the semiconductor component. The cooling structure includes a first substrate, a second substrate and a liquid coolant. The first substrate is disposed between the second substrate and the semiconductor component. The first substrate includes a thermal exchange cavity, and the liquid coolant is distributed in the thermal exchange cavity of the first substrate. The capping layer comprising a wetting region covered by the liquid coolant.

### BACKGROUND

Technological advances in integrated circuits (IC) materials and design have produced generations of IC (i.e., three-dimensional integrated circuit (3DIC)) having more compact and complex structures. The miniaturization of 3DIC has led to thermal management challenges. Therefore, there exists a need to provide an improved cooling mechanism to enhance the thermal dissipation performance of the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1L are schematic cross-sectional views illustrating structures produced at various stages of a manufacturing process of forming a cooling structure, in portion or entity, in accordance with some embodiments of the present disclosure.

FIG. 2A through FIG. 2C are schematic cross-section views illustrating intermediate stages of a manufacturing process of forming a cooling structure in accordance with another embodiment of the present disclosure.

FIG. 3A through FIG. 4D are schematic cross-sectional views illustrating structures produced at various stages of a manufacturing process of forming a cooling structure, in portion or entity, in accordance with some alternative embodiments of the disclosure.

FIG. 5A through FIG. 5D are schematic cross-sectional views illustrating structures produced at various stages of a manufacturing process of forming a semiconductor structure including a cooling structure, in portion or entity, in accordance with some embodiments of the disclosure.

FIG. 6A through FIG. 6D are schematic cross-sectional views illustrating structures produced at various stages of a manufacturing process of forming a semiconductor structure including a cooling structure, in portion or entity, in accordance with some alternative embodiments of the disclosure.

FIG. 7 is a schematic cross-sectional view illustrating a semiconductor structure including a cooling structure in accordance with some embodiments of the disclosure.

FIG. 8A through FIG. 10B are cross-section views and top views of a portion of a cooling structure, in accordance with some embodiments of the disclosure.

### DETAILED DESCRIPTION

The present disclosure relates generally to a cooling structure, and more particularly, to a cooling structure embedded in a carrier substrate and methods of manufacturing, for 3DIC.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, the manufacturing method is part of a package manufacturing process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Throughout the various views and illustrative embodiments, like reference numbers are used to designate like elements.

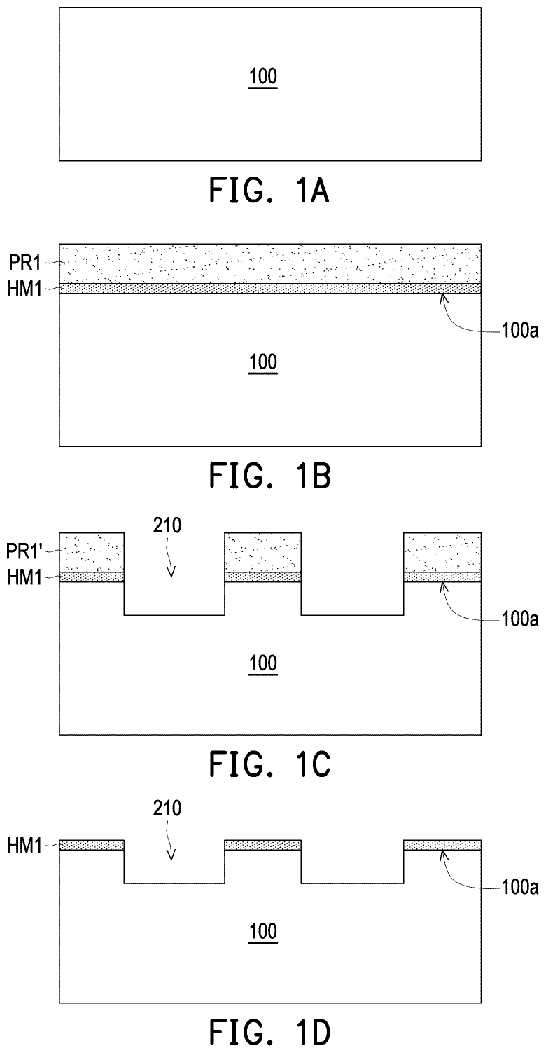

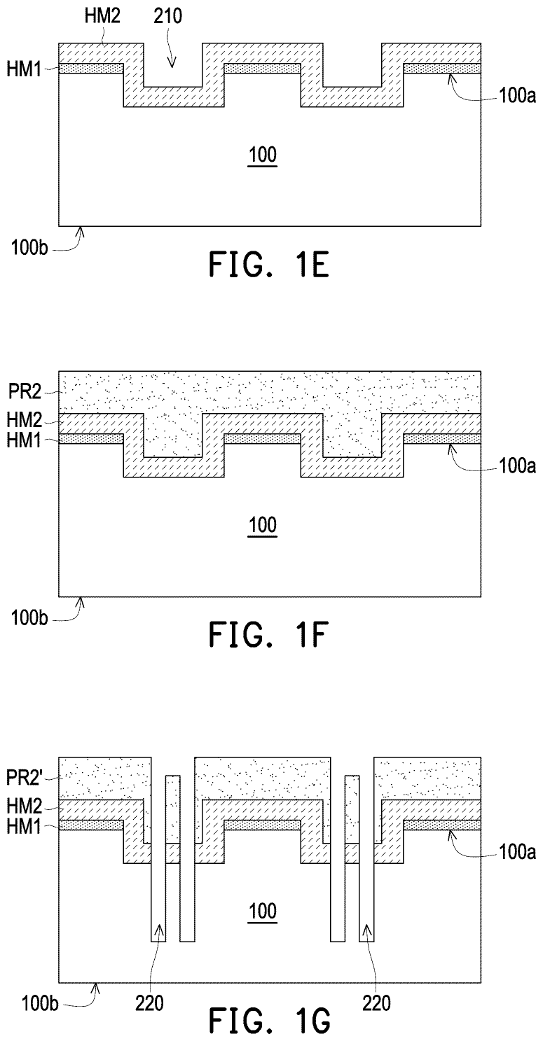

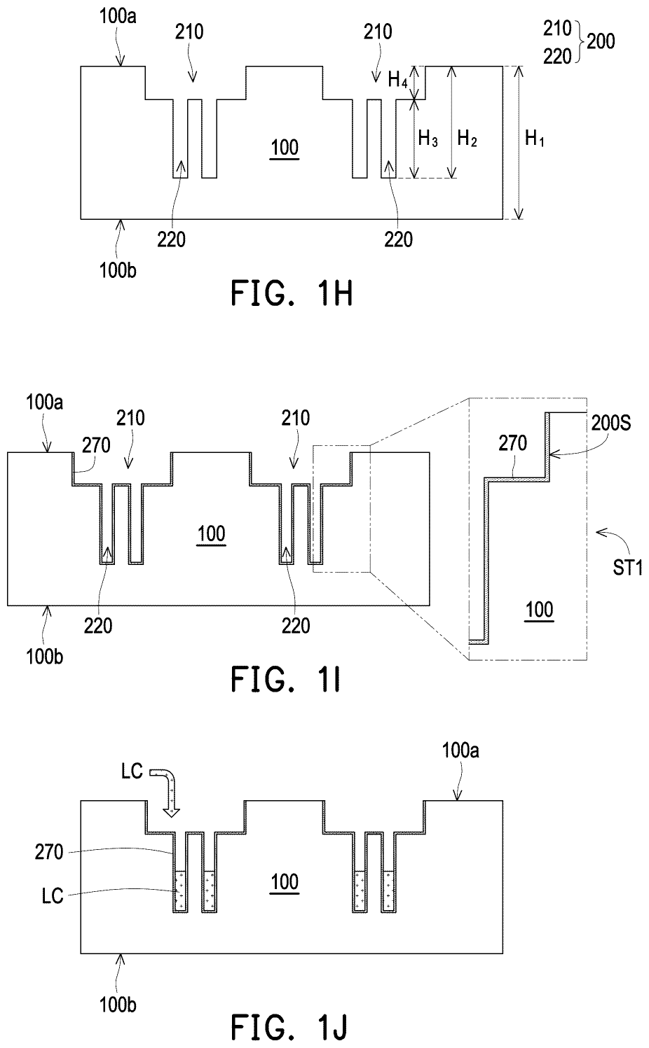

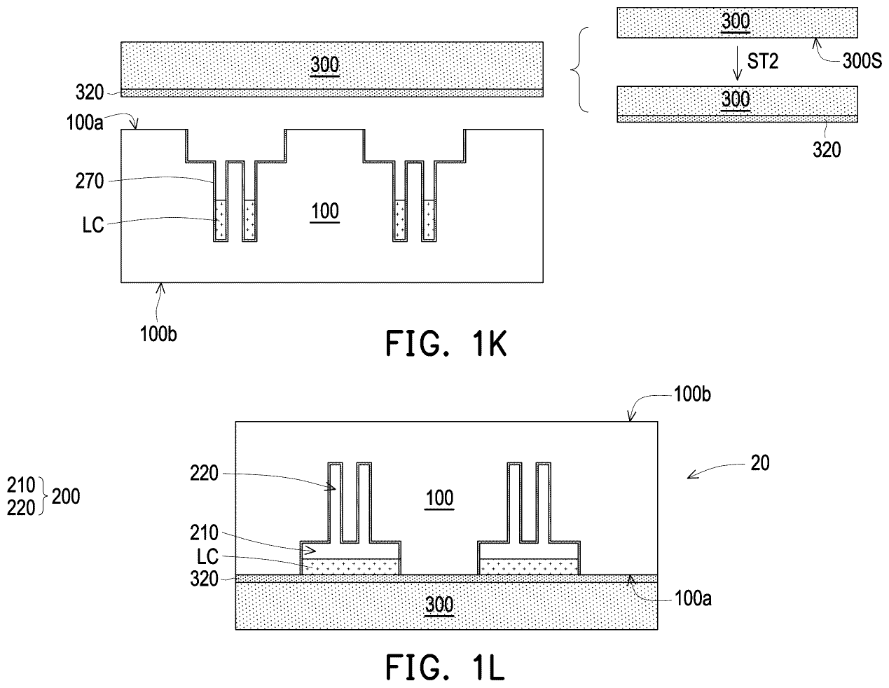

FIG. 1A through FIG. 1L are schematic cross-sectional views illustrating structures produced at various stages of a manufacturing process, in portion or entity, of forming a cooling structure 20. The cooling structure 20 includes a substrate 100 and a thermal exchange cavity 200 formed therein. The manufacturing process includes patterning a semiconductor substrate 100 according to some embodiments of the present disclosure. The method may be implemented, in whole or in part, by a system employing deep ultraviolet (DUV) lithography, electron beam (e-beam) lithography, x-ray lithography, and other lithography processes. Additional operations can be provided before, during, and after the method, and some operations described can be replaced, eliminated, or moved around for additional embodiments of the method.

Referring to FIG. 1A, the method for fabricating a cooling structure 20 includes the step of providing a substrate 100. In some embodiment, the substrate 100 is a semiconductor substrate such as a silicon substrate, it may also be formed of other semiconductor materials, such as silicon germanium, germanium, silicon carbon, aluminum nitride, gallium arsenide, boron nitride, silicon nitride, beryllium oxide, indium arsenide, indium gallium arsenide, indium antimonide, or the like. In some embodiments, the substrate 100 is a bulk mono-crystalline silicon substrate, a layer of silicon on a silicon wafer, a layer of a silicon-on-insulator (SOI) wafer, or a layer of a germanium-on-insulator (GeOI) wafer.

Referring to FIG. 1B, the method further includes forming a first hard mask layer HM1 on a first surface 100a of the substrate 100. The first hard mask layer HM1 includes one of: titanium nitride, silicon nitride, silicon oxynitride, silicon carbon nitride, and a combination thereof. The first hard mask layer HM1 is used to protect certain regions of the substrate 100 from various photolithographic processes such as etching and doping. Subsequently, a photo resist layer PR1 may be disposed over the substrate 100. Referring to FIG. 1C and FIG. 1D, in some embodiment, a first patterning process may be performed on the substrate 100, including soft baking the photo resist layer PR1, and exposing the photo resist layer PR1 to a radiation using a mask (not shown). The process further includes post-exposure baking, developing, and hard baking (i.e., the post development baking) to remove exposed portions of the photo resist layer PR1 and leaving unexposed portions of the photo resist layer PR1 thereof on the first hard mask layer HM1 as a patterned photo resist layer PR1′. The method is followed by an etching process to etch the first hard mask layer HM1 and substrate 100 uncovered by the patterned photo resist layer PR1′, to form trenches 210. After the etching process, the patterned photo resist layer PR1′ may be removed by wet stripping or plasma removal.

Referring to FIG. 1E through FIG. 1H, subsequently a second patterning process may be performed over the trench 210, thereby forming vias 220 within the trenches 210, extending partially through the substrate 100, from a first surface 100a of the substrate 100 towards the second surface 100b of the substrate 100. In some embodiment, as illustrate in FIG. 1E, a second hard mask layer HM2 may be provided on the first hard mask layer HM1, and another photo resist layer PR2 may be provided on the second hard mask HM2. Then, the steps to form the vias 220 in the substrate 100 may be similar to the process steps related to FIG. 1B through FIG. 1D. Similar or substantially the same method steps may be labelled with similar or the same reference signs or numbers as FIG. 1B through FIG. 1D, for illustration purposes, and details or descriptions (e.g., materials, formation process) of the same method steps shall not be repeated herein. In some embodiments, the trenches 210 is in communication with the vias 220. In another embodiment, the trenches 210 overlaps with the vias 220, and the vias 220 is located entirely within a span of the trenches 210. In some embodiments, as illustrated in FIG. 1H, a height H₁ of the substrate 100 is greater than a height H₂ of the thermal exchange cavity 200, and a height H₃ of the via 220 is greater than a height H₄ of the trench 210 of the thermal exchange cavity 200.

Referring to FIG. 1I and FIG. 1J, the method further includes performing a first surface treatment ST1 on at least a portion of inner sidewalls 200S of the thermal exchange cavity 200, to form a substantially uniform layer or a conformal layer of non-wetting region 270 on at least a portion of inner sidewalls 200S of the thermal exchange cavity 200. In an embodiment, the non-wetting region 270 is formed conforming to inner sidewalls 200S of the thermal exchange cavity 200. The dimension (i.e., thickness) of the non-wetting region 270 may be adjusted according to design and performance requirements. In some embodiment, the first surface treatment to form the non-wetting region 270 includes exposing the inner sidewalls 200S of the thermal exchange cavity 200 to plasma treatment with a reactant gas, wherein the reactant gas is at least one selected from the group consisting of hexamethyldisiloxane, octafluorocyclobutane, or tetrafluoromethane. In a subsequent step as illustrated in FIG. 1J, a liquid coolant LC may be introduced into at least a portion of the thermal exchange cavity 200, through the first surface 100a of the substrate 100.

Referring to FIG. 1K, in a next step, a capping layer 300 may be disposed on the substrate 100. Prior to disposing the capping layer 300 on the substrate 100, a second surface treatment ST2 is performed on a side or surface 300S of the capping layer 300 to be disposed on the substrate 100, to form a wetting region 320 on the side or surface 300S of the capping layer 300 facing the substrate 100. The wetting region 320 extends across substantially an entirety of the side or surface 300S of the capping layer 300. In some embodiments, the second surface treatment ST2 includes coupling a surface-treating agent having a polar functional group, including hydroxyl, carboxyl, or amine, or the like, on the side or surface 300S of the capping layer 300 facing the substrate 100. The dimension (i.e., thickness) of the wetting region 320 may be adjusted according to design and performance requirements. As the capping layer 300, it may be formed of semiconductor materials, such as silicon, silicon germanium, germanium, silicon carbon, aluminum nitride, gallium arsenide, boron nitride, silicon nitride, beryllium oxide, indium arsenide, indium gallium arsenide, indium antimonide, or the like.

Referring to FIG. 1L, the structure illustrated in FIG. 1K is flipped upside down or rotated 180 degrees, such that the liquid coolant LC within the thermal exchange cavity 200 is deposited in at least a region of the thermal exchange cavity 200 directly over the wetting region 320 of the capping layer 300, and the wetting region 320 on the capping layer 300 is covered by the liquid coolant LC. In some embodiment, a lateral width of the wetting region 320 may be the same as a lateral width of the substrate 100, and substantially greater than a lateral width of the thermal exchange cavity 200.

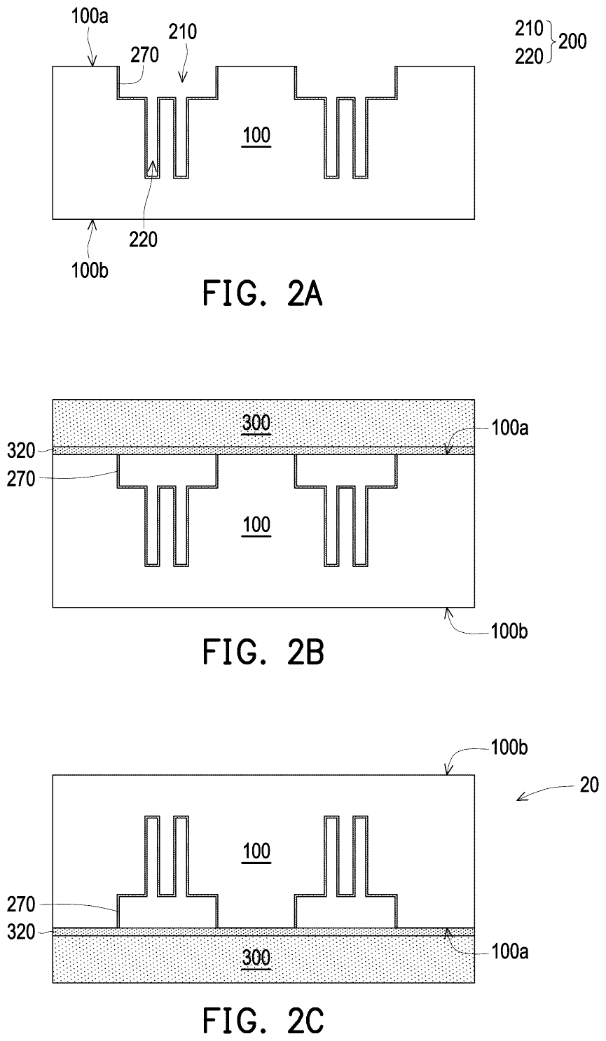

FIG. 2A through FIG. 2C are schematic cross-section views illustrating intermediate stages of a manufacturing process of forming a cooling structure 20 in accordance with another embodiment of the present disclosure.

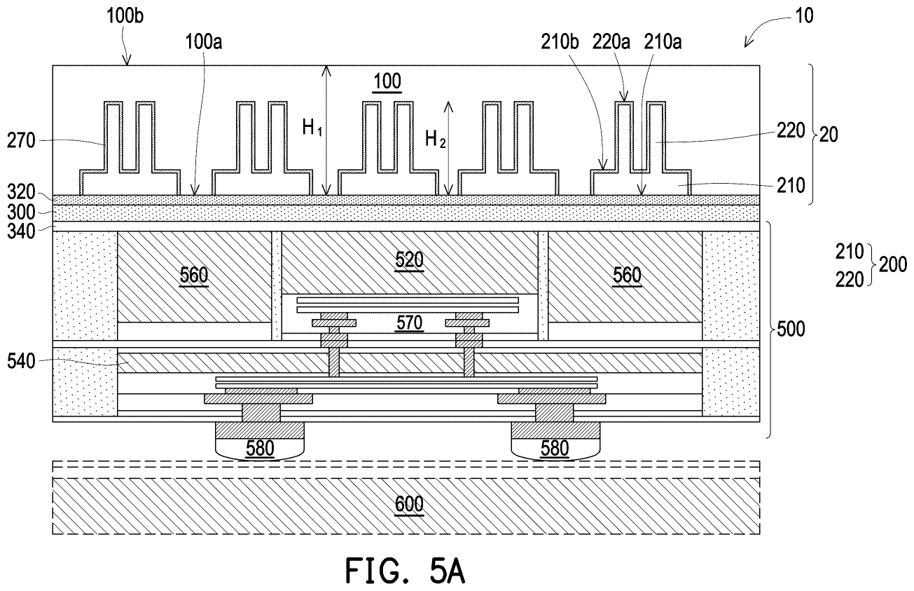

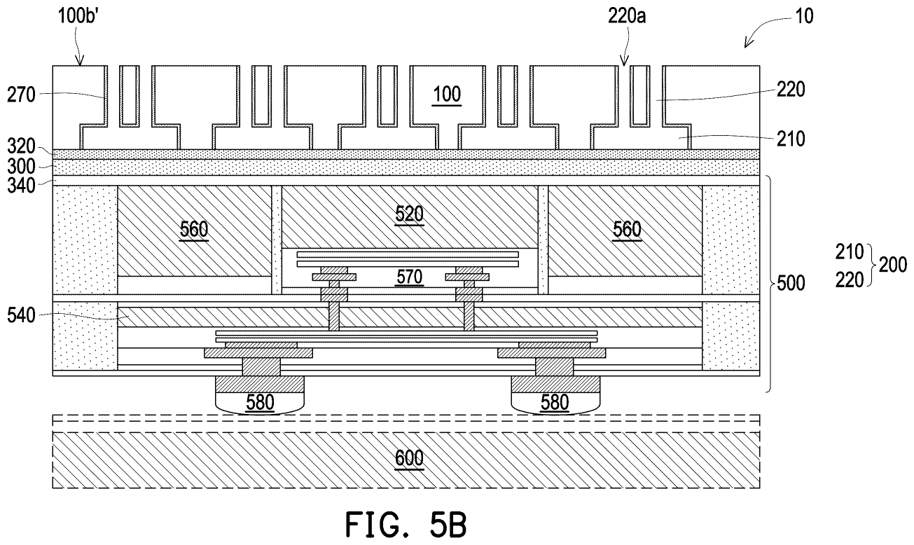

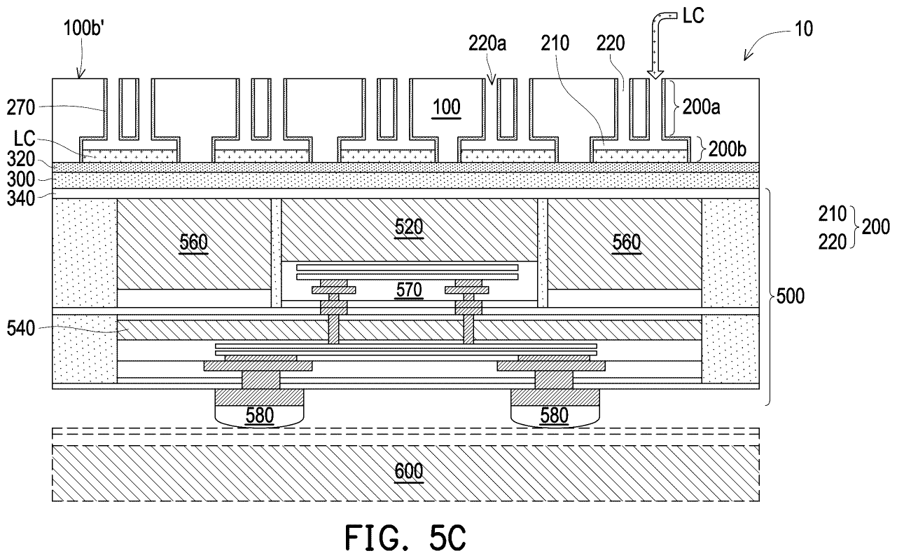

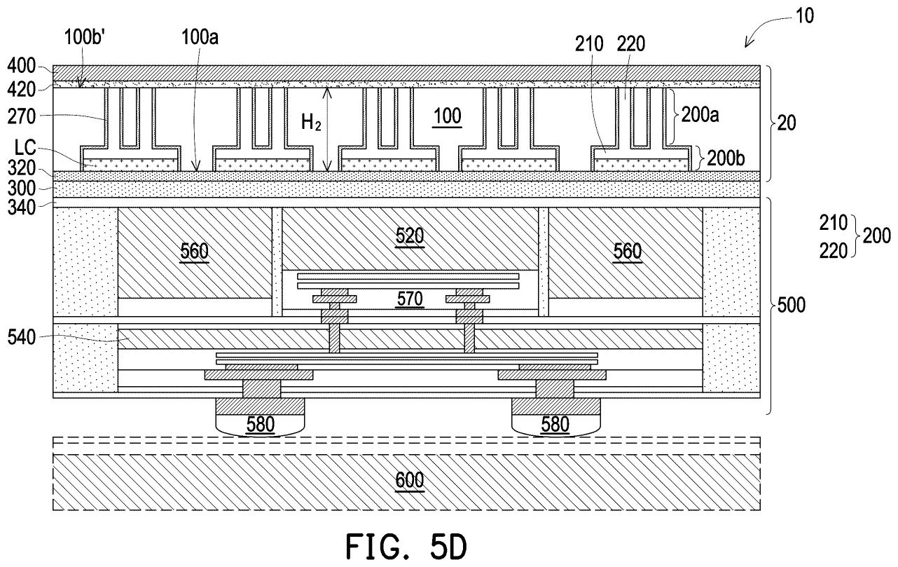

Referring to FIG. 2A through FIG. 2C, in some embodiments, during the formation of a cooling structure 20, the liquid coolant LC may not be introduced into the thermal exchange cavity 200 prior to disposing the capping layer 300 on the first surface 100a of the substrate 100, as illustrated in FIG. 1J. As shown in FIG. 2B and FIG. 2C, a void space may be formed within the thermal exchange cavity 200, which may be used for subsequent steps of processes as illustrated in FIG. 5A. The detailed description on the surface treatment ST1 to form the non-wetting region 270 on at least a portion of inner sidewalls 200S of the thermal exchange cavity 200, and the deposition of the capping layer 300 on the substrate 100, may be found in the text related to FIG. 1I through FIG. 1L, and will not be repeated herein.

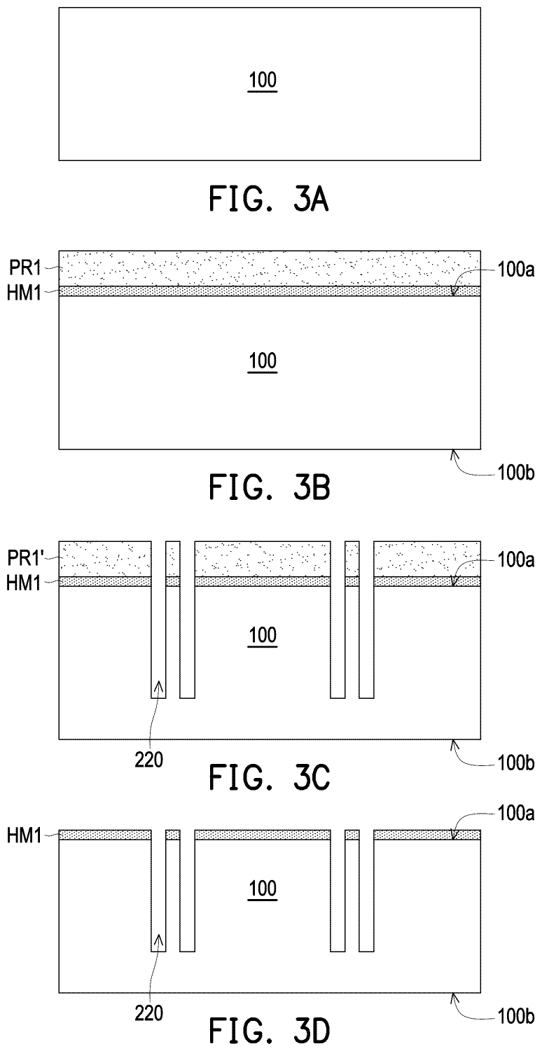

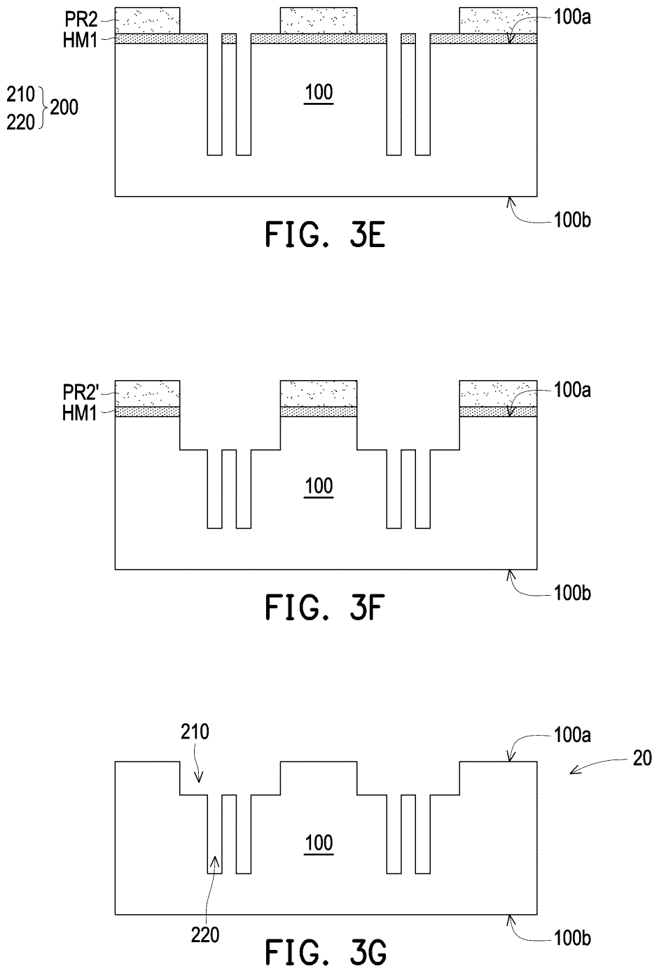

FIG. 3A through FIG. 3G are schematic cross-sectional views illustrating structures produced at various stages of a manufacturing process of forming a cooling structure 20 including a substrate 100 and a thermal exchange cavity 200, wherein the thermal exchange cavity 200 includes trenches 210 and vias 220, in accordance with some alternative embodiments of the disclosure. In some embodiments, the process includes a first patterning step of forming vias 220 (as illustrated in FIG. 3C and FIG. 3D), followed by a second patterning step of forming trenches 210 (as illustrated in FIG. 3E and FIG. 3F), within the substrate 100. The process steps and materials used for forming the exemplary structures are similar to the process steps and materials described with reference to FIG. 1A through FIG. 1H and in the previous paragraphs, so the detailed descriptions thereof shall be omitted herein. Similar or substantially the same structural parts or elements may be labelled with similar or the same reference numbers as FIG. 1A through FIG. 1H, for illustration purposes.

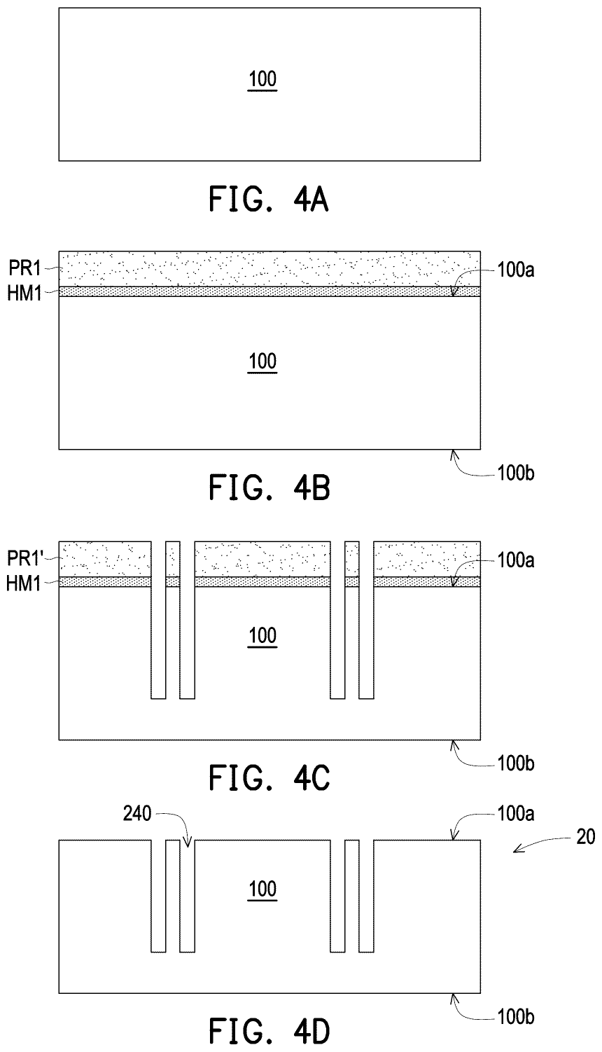

FIG. 4A through FIG. 4D are schematic cross-sectional views illustrating structures produced at various stages of a manufacturing process of forming a cooling structure 20 including trenches 240, in portion or entity, in accordance with some alternative embodiments of the disclosure. The process steps and materials used for forming the exemplary structures are similar to the process steps and materials described with reference to FIG. 1A through FIG. 1D and in the previous paragraphs, related to the formation of the trenches 210 within the substrate 100. Consequently, the detailed descriptions thereof shall be omitted herein. Similar or substantially the same structural parts or elements may be labelled with similar or the same reference numbers as FIG. 1A through FIG. 1D, for illustration purposes.

FIG. 5A through FIG. 5D are schematic cross-sectional views illustrating structures produced at various stages of a manufacturing process of forming a semiconductor structure 10 having a cooling structure 20, in portion or entity, in accordance with some embodiments of the disclosure.

Referring to FIG. 5A, a semiconductor structure 10 is provided. The semiconductor structure 10 includes a cooling structure 20, including a first substrate 100 and a thermal exchange cavity 200 embedded therein, and a semiconductor component 500. In some embodiment, the semiconductor component 500 is disposed on the first surface 100a of the first substrate 100. In some embodiments, a capping layer 300 may be interposed between the first substrate 100 and the semiconductor component 500. The capping layer 300 includes a wetting region 320 formed on a side of the capping layer 300 facing the thermal exchange cavity 200 of the cooling structure 20. In some embodiment, the semiconductor component 500 may be adhered (attached) to the cooling structure 20 through a bonding film 340 formed on the capping layer 300. In some embodiments, the bonding film 340 may be selected from adhesives, adhesive films, epoxy resin and equivalent thereof. In some embodiments, the wetting region 320 and the bonding film 340 may be disposed at opposing sides of the capping layer 300.

In some embodiment, the thermal exchange cavity 200 includes a base portion 210 and an elongated portion 220, wherein a first side 210a of the base portion 210 is disposed on and substantially levelled with the first surface 100a of the first substrate 100, and the elongated portion 220 vertically extends from a second side 210b of the base portion 210 in a direction substantially perpendicular to the base portion 210. In some embodiment, the base portion 210 may have a shape of a trench, and the elongated portion 220 may have a shape of a via, a rod, a pillar, or similar structures as required.

Still referring to FIG. 5A, in some embodiment, a height H₁ of the first substrate 100 is substantially greater than a height H₂ of the thermal exchange cavity 200, such that top ends 220a of the elongated portion 220 of the thermal exchange cavity 200 is substantially lower than a second surface 100b of the first substrate 100. In some embodiments, the thermal exchange cavity 200 in the first substrate 100 may be thermally connected to the capping layer 300, and the semiconductor component 500 may be thermally connected to, and electrically insulated from the first substrate 100. In some embodiment, as illustrated in FIG. 5A, the semiconductor component 500 includes structures 520, 540 and 560, which may independently include one of a processor die, memory die (e.g., a high-bandwidth-memory (HBM) die, random access memory (RAM), such as dynamic RAM (DRAM), static RAM (SRAM), flash memory, magneto-resistive memory, or another suitable type of memory), power device die, an ASIC (application specific integrated circuit) die, a logic die, a central processing unit (CPU) die, a graphic processing unit (GPU) die, a micro control unit (MCU) die, an input-output (I/O) die, a baseband (BB) die, or a system-on-chip (SoC) die, or other functional device dies. In some embodiments, the semiconductor component 500 may further include a structure 570, which may include an interposer, a passive die, or another suitable connecting structure. In some embodiments, the structure 570 may independently include a plurality of through silicon vias (TSVs) (not shown) for inter-die communication, silicon or other semiconductor materials and may include one or more conductive layers (not shown). In some embodiments, multiple metallization layers (not shown) are formed within structure 570, and structure 570 may include a plurality of other layers, such as inter-metal dielectric (IMD) layers (not shown). In some other embodiments, other active components or circuits, such as transistors, capacitors, and other devices may be included in the semiconductor component 500.

In an embodiment, the semiconductor component 500 includes a die stack of one or more semiconductors dies 520, 540, wherein the die stack and the first substrate 100 are located at opposing side of the capping layer 300, and the die stack and the first substrate 100 are thermally coupled and electrically insulated with each other. In some embodiments, the die stack includes a first semiconductor die 520 and a second semiconductor die 540, wherein the first semiconductor die 520 is electrically connected to the second semiconductor die 540, and the first semiconductor die 520 is located between the second semiconductor die 540 and the cooling structure 20. In an embodiment, the first semiconductor die 520 is thermally connected to the thermal exchange cavity 200 of the cooling structure 20, through the capping layer 300. In an embodiment, the total area of thermal exchange cavity 200 in contact with the capping layer 300 is larger than an area of the first semiconductor die 520. In some embodiments, the area of the thermal exchange cavity 200 in contact with the capping layer 300 is greater than twice the area of the first semiconductor die 520. In some embodiments, the ratio of the area of the thermal exchange cavity 200 in contact with the capping layer 300 to the area of the first semiconductor die 520 is in a range from about 2 to about 4. If the ratio of the area of the thermal exchange cavity 200 in contact with the capping layer 300 to the area of the first semiconductor die 520 is too small, the thermal exchange cavity 200 may not effectively dissipate heat from the first semiconductor die 520. If the ratio is too large, the overall size of the semiconductor structure 10 is increased without a significant increase in heat dissipation capability. Even though a first semiconductor die 520 and a second semiconductor die 540 are shown in FIG. 5A, it is understood that a plurality of semiconductor dies may be bonded, and the number of the semiconductor dies used in the semiconductor component 500 is not limited by the embodiments herein. In some embodiments, the semiconductor dies 520, 540 may be the same type of dies or perform the same functions. In other embodiments, the semiconductor dies 520, 540 may be different types of dies or perform different functions. In some embodiment, a plurality of memory dies 560 may be formed beside the first semiconductor die 520, such that the first semiconductor die 520 is between the plurality of memory dies 560 and the first substrate 100. In some embodiments, the first semiconductor die 520 may be connected to the second semiconductor die 540 through structure 570. The structure 570 includes metal lines and vias (not shown) formed therein and electrically coupled to the first and the second semiconductor dies 520, 540. The metal lines and vias may be formed of copper and copper alloys, and may be formed using damascence processes. In another embodiment, the structure 570 may include a redistribution structure and a plurality of conductive pillars formed between the first and the second semiconductor dies 520, 240.

In some embodiment, the semiconductor component 500 may include conductive connectors 580 at a bottom surface of the semiconductor component 500, to be electrically connected to a corresponding terminal on a semiconductor die or a next level substrate or component 600. The conductive connectors 580 include any suitable types of structure capable of forming an electrical connection with a corresponding component, including solder bumps, controlled collapse chip connection (C4) bump, solder balls or the like.

Referring to FIG. 5B, in some embodiment, a thinning process may be performed to the second surface 100b of the first substrate 100 and a portion of the first substrate 100 may be removed until top ends 220a of the underlying elongated portion 220 of the thermal exchange cavity 200 are revealed from the first substrate 100, and forming a surface 100b′ of the first substrate 100. In some embodiments, the thinning process includes a chemical mechanical polishing (CMP) process, back-grinding, or an etching process. In some embodiments, the top ends 220a of the elongated portion 220 are substantially level with one another and are level with the surface 100b′ of the first substrate 100.

Referring to FIG. 5C, in some embodiment, a liquid coolant LC may be introduced into at least a portion of the thermal exchange cavity 200, through the top ends 220a of the elongated portion 220 of the thermal exchange cavity 200. In some embodiment, the liquid coolant LC is distributed in a bottom region 200b of the thermal exchange cavity 200, and the liquid coolant LC is in contact with the wetting region 320 of the capping layer 300, and covering a portion of the wetting region 320 of the capping layer 300. In some embodiment, an upper region 200a of the thermal exchange cavity 200 is not occupied by the liquid coolant LC. The wetting region 320 of the capping layer 300 provides a hydrophilic surface to help increase direct contact between the liquid coolant LC and the capping layer 300, to increase the efficiency of heat transfer from the semiconductor component 500 to the liquid coolant LC. The increase in heat transfer efficiency helps to maintain a constant temperature within the semiconductor component 500 within an acceptable range, to prevent damage of the operating devices (i.e., semiconductor dies 520, 540) within the semiconductor component 500.

In some embodiments, the liquid coolant includes a two-phase vaporizable liquid, such as alcohol, for example ethanol, methanol, propanol, isopropyl alcohol, acetone, glycol-based coolants, silicone-based coolants, fluoro-carbon based coolants, or any liquid of the like, being capable of vaporizing and possessing a relatively high latent heat, in order to transfer heat away from the semiconductor component 500. The two-phase vaporizable liquid may further include other synthetic coolants having a vapor temperature below 100° C., depending on performance requirements. One skilled in the art will understand that the liquid coolant LC may be any liquid capable of absorbing and releasing thermal energy and may be in a fluid form.

Referring to FIG. 5D, the semiconductor structure 10 further includes a second substrate 400 disposed on the surface 100b′ of the first substrate 100, and in contact with the elongated portion 220 of the thermal exchange cavity 200 penetrating through the first substrate 100, such that the thermal exchange cavity 200 is embedded in an enclosed space between the first substrate 100 and the second substrate 400. The second substrate 400 may be formed directly on, and in physical contact with, the elongated portion 220 of the thermal exchange cavity 200. In some embodiments, a thermal interface material (TIM) layer 420 may be disposed over at least the surface 100b′ of the first substrate 100, in between the first substrate 100 and the second substrate 400. The first substrate 100 is thermally connected to the second substrate 400 via the thermal interface material (TIM) layer 420. The thermal interface material (TIM) layer 420 may be interposed between the first substrate 100 and the second substrate 400, to even out the contact surfaces of the first substrate 100 and the second substrate 400, in order to improve the thermal conductivity and alleviates pressure exerted by the second substrate 400 on the first substrate 100. Suitable thermal interface material (TIM) layer 420 should have high thermal conductivity and should improve thermal contact when disposed between the first substrate 100 and the second substrate 400. Examples of thermal interface material (TIM) 420 includes, but are not limited to, thermal greases, silver filled epoxy or the like, polymer-solder hybrid thermal interface material, and indium foil. The thickness of the thermal interface material (TIM) layer 420 will vary depending upon the performance requirements of the first substrate 100. In some embodiment, the thickness of the thermal interface material (TIM) layer 420 varies from about 50 μm to about 100 μm. The thermal interface material (TIM) layer 420 may be formed by spin-on coating, printing, physical vapor deposition (PVD) or another suitable formation process.

Still referring to FIG. 5D, in some embodiment, the second substrate 400 formed over the first substrate 100, may be a metal lid or a heat pipe, capable of conducting heat away from the cooling structure 20. In some embodiments, the second substrate 400 may be made of a material possessing high thermal conductivity, including aluminum, copper, silver, gold, nickel, tungsten, alloys thereof, and/or multi-layers thereof. In an exemplary embodiment, the second substrate 400 may be thermally coupled to the semiconductor component 500, through the underlying thermal exchange cavity 200 embedded within the first substrate 100. It should be noted that the thickness of the second substrate 400 depends on several factors, but not limited to, the heat dissipation rate of the cooling structure 20, thermal conductivity of the material, surface area of the cooling structure 20, and the required size of the finished semiconductor structure 10.

As illustrated in FIG. 5D, the liquid coolant LC is shown to predominantly reside in the bottom region 200b of the thermal exchange cavity 200. The liquid coolant LC helps to cool the semiconductor component 500 by absorbing heat generated by the operating devices within the semiconductor component 500. When the semiconductor dies 520, 540 in the semiconductor component 500 are in operation, heat generated by the semiconductor dies 520, 540 will heat up the liquid coolant LC contained in the thermal exchange cavity 200, a portion of the liquid coolant LC evaporates due to an increase in temperature of the liquid coolant LC. The vaporized liquid coolant LC rises to fill the thermal exchange cavity 200, and when the vaporized liquid coolant LC contacts the upper portion 200a of the thermal exchange cavity 200, it releases its latent heat of vaporization and condenses to liquid state (i.e., liquid condensate). Heat is then transferred to the surrounding environment through the cooling structure 20, and the liquid condensate flows back to the reservoir of liquid coolant LC at the bottom region 200b of the thermal exchange cavity 200. In some embodiment, a non-wetting region 270 may be formed on the inner sidewalls 200S of the thermal exchange cavity 200 through a first surface treatment ST1 (as previously shown in FIG. 1I), to facilitate the reflow of the liquid condensate from the upper region 200a to the bottom region 200b of the thermal exchange cavity 200. A thermal exchange cycle removes the heat generated by the semiconductor dies 520, 540 and other electronic components in the semiconductor component 500. In some embodiments, the first surface treatment ST1 modifies the surface chemistry of the thermal exchange cavity 200 within the first substrate 100, thereby creating a non-wetting region 270 which is hydrophobic and water repellent. The hydrophobic nature of the non-wetting region 270 lowers the capillary force acting between the liquid condensate and the inner sidewalls 200S of the thermal exchange cavity 200, to promote the reflow of the liquid condensate to the bottom region 200b of the thermal exchange cavity 200, and bring the liquid coolant LC into engagement with the semiconductor component 500 again, to begin the thermal exchange cycle anew. The non-wetting region 270 prevents the liquid coolant LC from remaining in the upper region 200a of the thermal exchange cavity 200, following condensation. Thereby, helping to maintain a level of the liquid coolant LC within the bottom region 200b of the thermal exchange cavity 200. In some embodiments, the thermal exchange cavity 200 provides a sufficient volume for evaporation of the liquid coolant LC, efficiently conducts heat from the semiconductor component 500 during the thermal exchange process, and avoids unnecessarily increasing the size of the semiconductor structure 10.

Still referring to FIG. 5D, in some embodiment, the liquid coolant LC may be in contact with the wetting region 320 of the capping region. The wetting region 320 provides a hydrophilic interface, and promotes effective spreading of the liquid coolant LC across the bottom region 200b of the thermal exchange cavity 200, thereby preventing dry out at hot spots above the semiconductor component 500, and facilitating efficient heat transfer from the semiconductor component 500 to the liquid coolant LC. As used herein, the “hot spot” may refer to a region of the semiconductor component 500 proximate the semiconductor dies 520, 540 or other heat source at which temperature of the semiconductor component 500 is the highest.

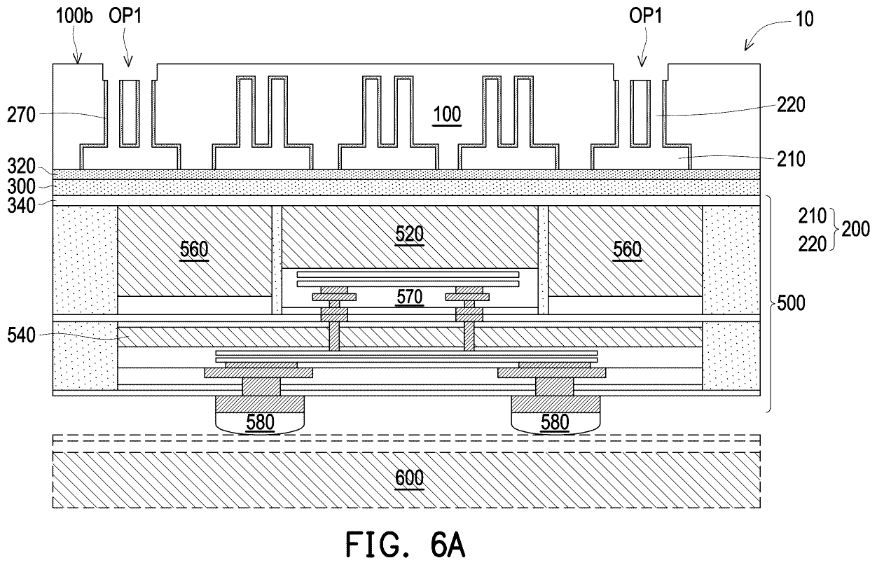

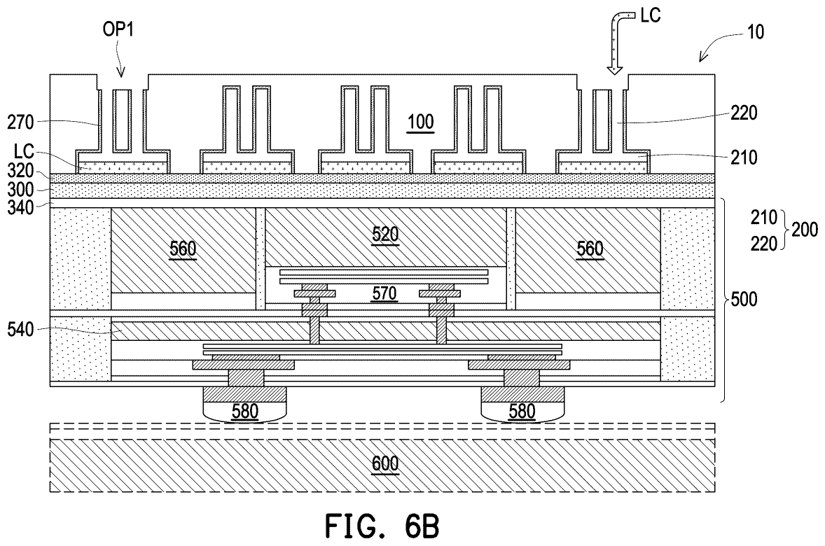

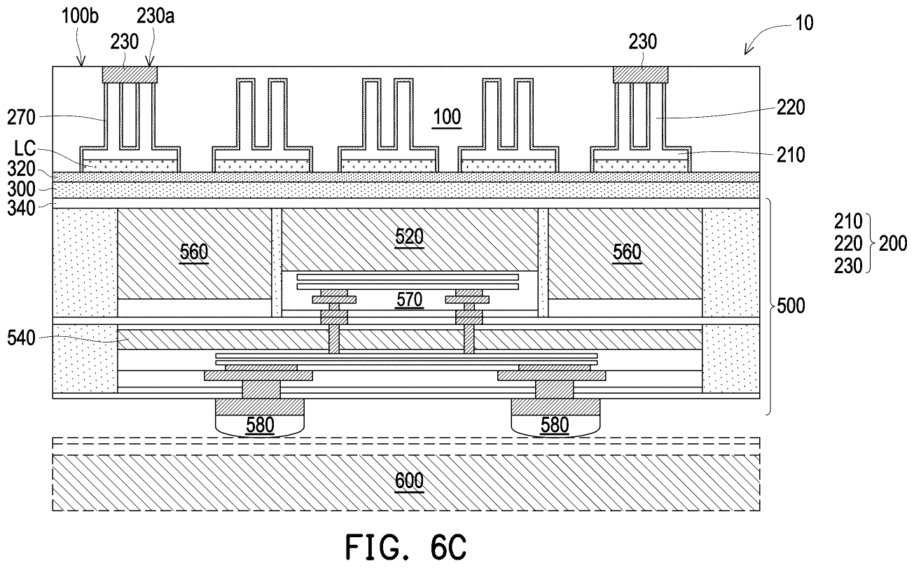

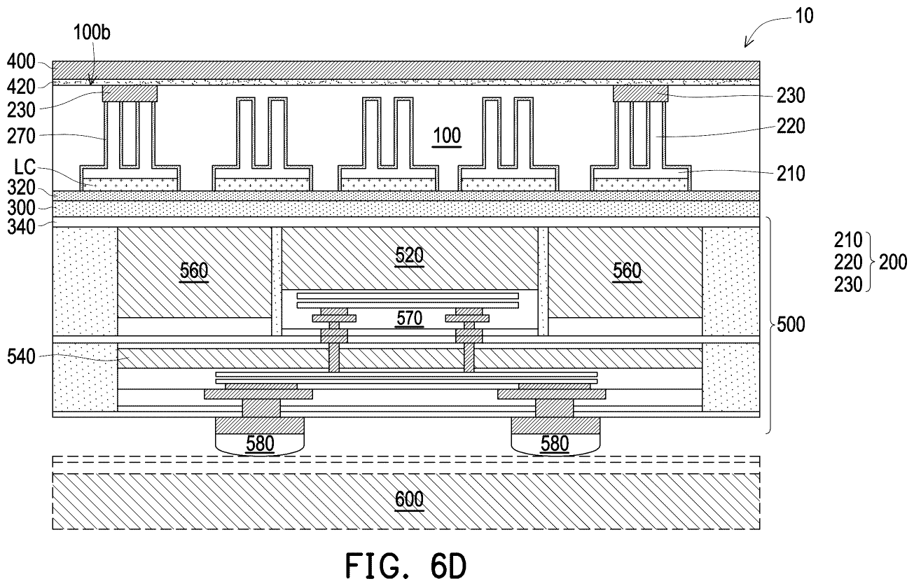

Referring to FIG. 6A, in some embodiments, the first substrate 100 is patterned to remove a portion of the first substrate 100 above the elongated portion 220 of the thermal exchange cavity 200 to form at least one or a plurality of openings OP1 extending from the second surface 100b of the first substrate 100 to the top ends 220a of the elongated portion 220 of the thermal exchange cavity 200, thereby exposing the underlying elongated portion 220 of the thermal exchange cavity 200. In some embodiments, the first substrate 100 is patterned by etching, laser drilling, or other suitable patterning technique. Next, referring to FIG. 6B, a liquid coolant LC may be disposed into the thermal exchange cavity 200 through the opening OP1 located on top of the elongated portion 220. Subsequently, referring to FIG. 6C, a top portion 230 may be formed on the elongated portion 220, exposed by the openings OP1. In an embodiment, the top portion 230 and the base portion 210 are at opposing sides of the elongated portion 220 of the thermal exchange cavity 200, and a top surface 230a of the top portion 230 is substantially levelled with the second surface 100b of the first substrate 100. In some embodiments, the top portion 230 includes a metal lid, formed of a thermal conductive material selected from a group including aluminum, copper, silver, gold, nickel, tungsten, or alloys thereof.

Referring to FIG. 6D, a second substrate 400 may be formed over the first substrate 100, and covering the underlying top portion 230 of the thermal exchange cavity 200. In some embodiments, the second substrate 400 has a lateral dimension greater than a lateral dimension of the top portion 230 of the thermal exchange cavity 200. In some embodiments, the top portion 230 is configured to provide thermal connections between the thermal exchange cavity 200 and the second substrate 400. In some embodiments, a thermal interface material (TIM) layer 420 may be disposed on the top portion 230 of the thermal exchange cavity 200. In some embodiments, the thermal interface material (TIM) layer 420 may be interposed between the top portion 230 of the thermal exchange cavity 200 and the second substrate 400. Examples of thermal interface material (TIM) 420 includes, but are not limited to, thermal greases, silver filled epoxy or the like, polymer-solder hybrid thermal interface material, and indium foil.

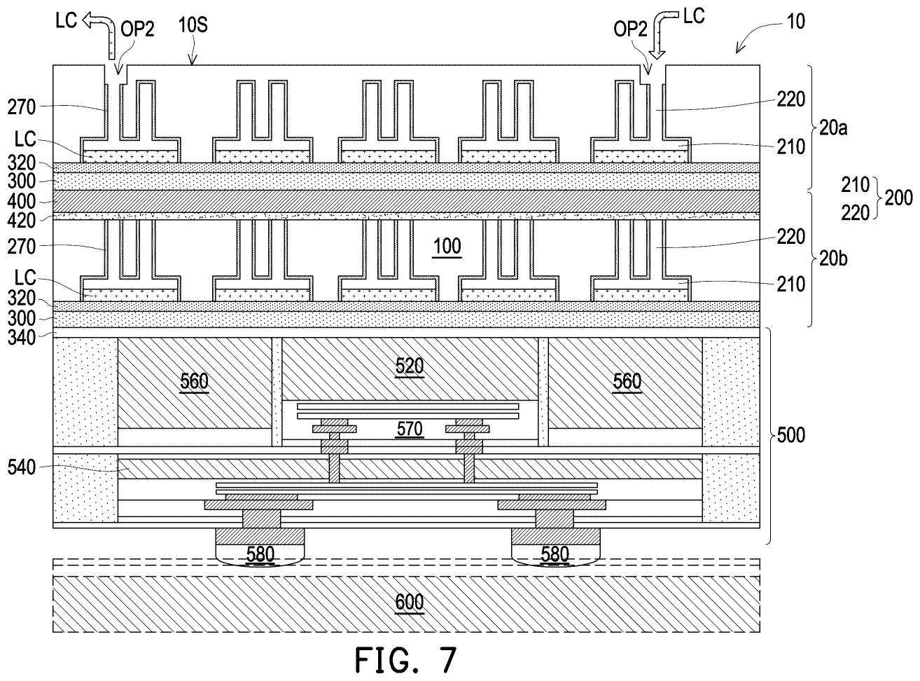

Referring to FIG. 7, in some embodiments, a plurality of cooling structures 20a, 20b of the same or different sizes, dimensions and configurations may be disposed over the semiconductor component 500. In an embodiment, as shown in FIG. 7, two cooling structures 20a, 20b may be disposed over the semiconductor component 500 in a stacked-up manner. Although FIG. 7 shows a semiconductor structure 10 as having two cooling structures 20a, 20b stacked upon one another, one skilled in the art will understand that the semiconductor structure 10 may have more than two cooling structures arranged in a linear or stack up manner over the semiconductor component 500. In some embodiments, as illustrated in FIG. 7, the cooling structure 20a at a top-most position, farthest away from the semiconductor component 500 may not be capped or sealed at a top-most surface 10S of the cooling structure 20a. In an alternative embodiment, the cooling structure 20a may include at least one or a plurality of openings OP2 extending from the top-most surface 10S of the cooling structure 20a to the top ends 220a of the elongated portion 220 of the thermal exchange cavity 200, configured to permit flow of liquid coolant LC into and out of the cooling structure 20a, to improve the overall thermal dissipation performance of the semiconductor structure 10. In some embodiments, the openings OP2 are formed simultaneously. In some embodiments, the openings OP2 are formed sequentially. Openings OP2 may be formed in the substrate 100 by a process, including etching, laser drilling or other suitable material removal process.

In another embodiment, a second substrate 400 including a thermal conductive lid, may be deposited on the cooling structure 20a. In some embodiments, the thermal conductive lid may be made of a material possessing high thermal conductivity, such as copper, copper alloy, tungsten, or the like. In some embodiments, a thermal interface material (TIM) layer 420 may be disposed between the first substrate 100 and the second substrate 400 of the cooling structure 20a. The configuration shown in FIG. 7 merely serves as an exemplary illustration. However, the disclosure is not limited thereto. Multiple cooling structures may be formed in various orientation across the semiconductor component 500 to enhance the thermal dissipation performance of the 3DIC.

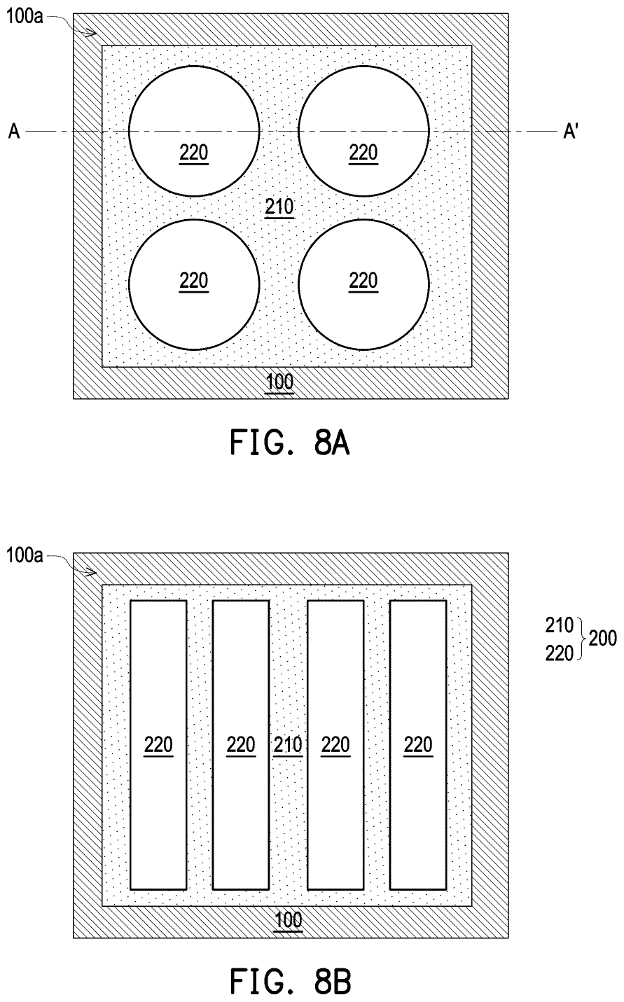

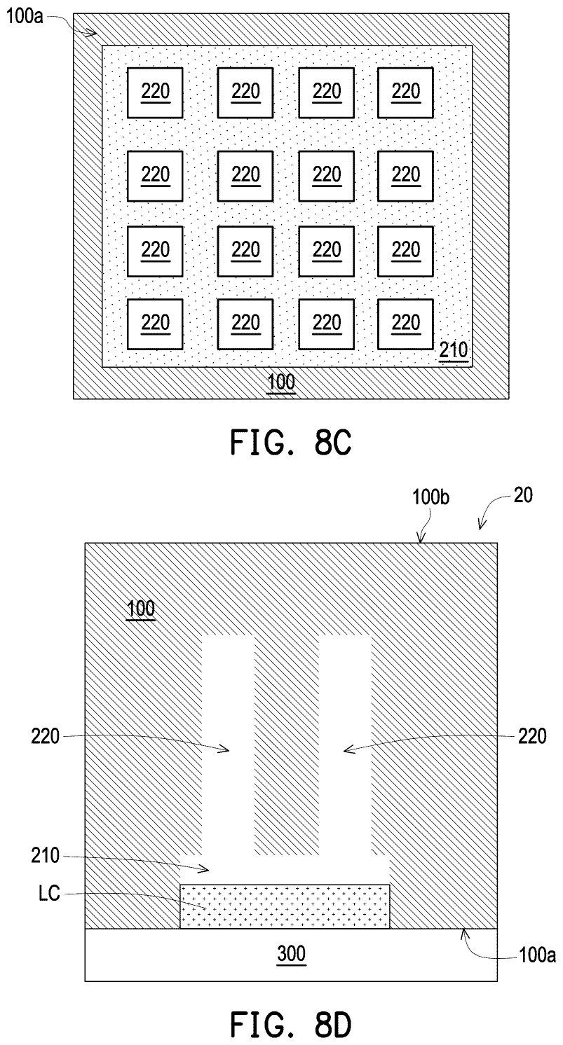

FIG. 8A through FIG. 10B are cross-sectional views and top views of a portion of the cooling structure 20, in accordance with some embodiments of the disclosure.

FIG. 8A through FIG. 8C are top views of a portion of a cooling structure 20 including a substrate 100 and a thermal exchange cavity 200 formed therein, as examples of possible configurations of the thermal exchange cavity 200 including a trench 210 and a via 220, according to some embodiments of the present disclosure. FIG. 8D is a cross-sectional view taken along a line A-A′ depicted in the top view of FIG. 8A.

In some embodiment, the thermal exchange cavity 200 may include thermal dissipating pillars, columns, fins, trenches, or other types of thermal dissipating structure configured to dissipate heat from the semiconductor component 500. In an embodiment, the thermal exchange cavity 200 as depicted in FIG. 8A through FIG. 8D are shown to include a trench 210 and a via 220, extending partially through the substrate 100, from a first surface 100a towards a second surface 100b of the substrate 100, wherein the via 220 is in communication with the trench 210. In some embodiment, a pattern density of the trench 210 over the substrate 100 is approximately 10 to 90 percent of the total surface area of the substrate 100, preferably 20 to 80 percent, and more preferably 40 to 60 percent. The pattern density of the trench 210 is defined by the total area of the trench 210 located within the substrate 100, divided by the total area of the substrate 100.

FIG. 8A through FIG. 8C illustrates examples of possible cross-sectional profiles of the via 220 of the thermal exchange cavity 200, according to some embodiments of the present disclosure. In some embodiments, the via 220 may have a symmetrical polygonal cross-sectional profile, for example, a square-shaped, a rectangular-shaped, a spherical shape profile, however, the disclosure is not specifically limited thereto. In some embodiments, the via 220 having other different shapes may be contemplated, as long as the shapes and designs are capable of placing the liquid coolant LC and semiconductor component 500 in efficient heat exchange with one another. In some embodiments, the via 220 are positioned within a space defined by the trench 210 such that the via 220 overlaps the trench 210, and the via 220 is completely located within the span of the trench 210. In some embodiment, a pattern density of the via 220 over the trench 210 is approximately 10 to 90 percent of the total surface area of the trench 210, preferably 20 to 80 percent, and more preferably 40 to 60 percent. The pattern density of the via 220 is defined by the total area of the via 220 located within the trench 210, divided by the total area of the trench 210. The thermal exchange cavity 200 may be configured to have a relatively large surface area, through the inclusion of multiple trenches 210 and vias 220, to increase the thermal capacity of the cooling structure 20. The pattern density, positions and dimensions (i.e., size, width, length) of the trench 210 and via 220 of the thermal exchange cavity 200 may be adjusted based on experimentation to optimize the thermal dissipation performance of the cooling structure 20. While the illustrations all show via 220 of one consistent width within the same configuration, it should be noted that a consistent width is not necessary. The width of the via 220 may be varied depending on the application. FIG. 8D is a schematic cross-sectional view illustrating a cooling structure 20, according to some embodiments of the present disclosure, wherein the cross-sectional view is taken along a line A-A′ depicted in the plane view of FIG. 8A. In an embodiment, the cooling structure 20 includes a thermal exchange cavity 200 embedded in the first substrate 100. The thermal exchange cavity 200 includes a trench 210 and a via 220, extending partially through the first substrate 100, from a first surface 100a of the first substrate 100 towards a second surface 100b of the first substrate, and the trench 210 is in communication with the via 220. The cooling structure 20 further includes a liquid coolant LC distributed in at least a portion of the trench 210 in the thermal exchange cavity 200, and a capping layer 300 disposed on the first surface 100a of the substrate 100, wherein the liquid coolant LC is in contact with the capping layer 300.

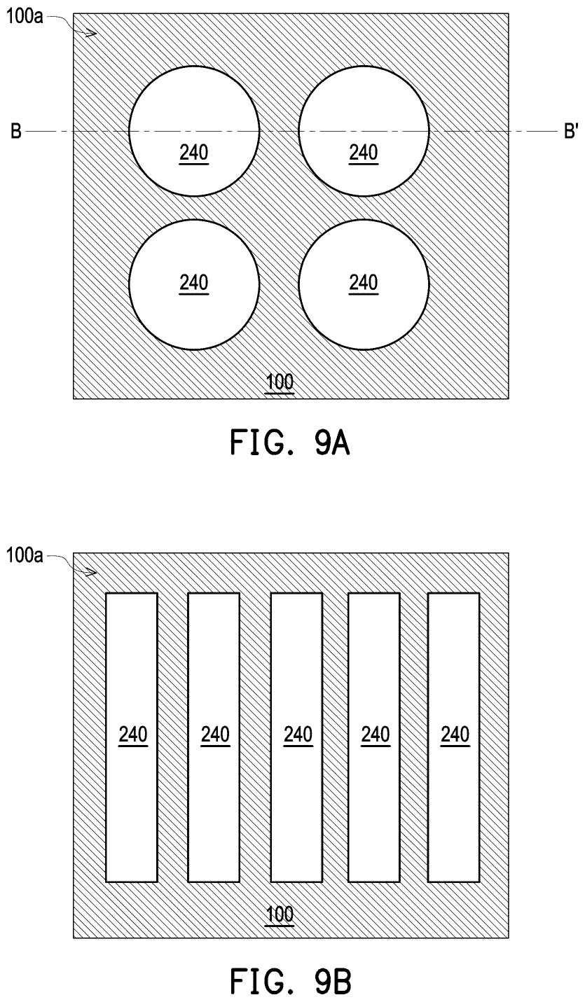

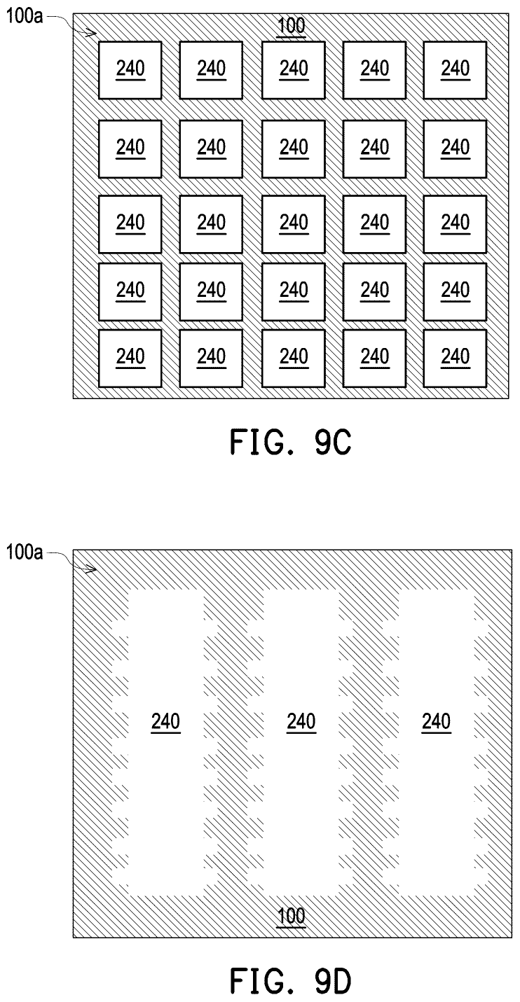

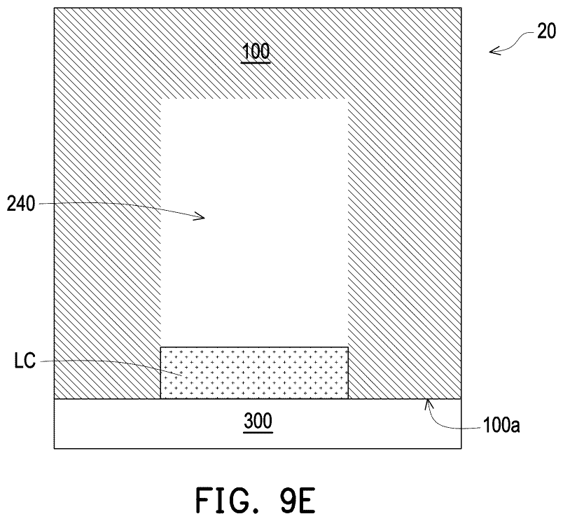

FIG. 9A through FIG. 9D illustrate top views of a portion of a cooling structure 20 including a substrate 100 and a thermal exchange cavity 200 formed therein, as examples of possible configuration of the thermal exchange cavity 200 including a trench 240, according to some embodiments of the present disclosure. FIG. 9E is a cross-sectional view taken along a line B-B′ depicted in the top view of FIG. 9A. In some embodiment, a pattern density of the trench 240 over the substrate 100 is approximately 10 to 90 percent of the total surface area of the substrate 100, preferably 20 to 80 percent, and more preferably 40 to 60 percent. The pattern density of the trench 240 is defined by the total area of the trench 240 located within the substrate 100, divided by the total area of the substrate 100.

In some embodiments, as illustrated in FIG. 9A through FIG. 9C, the trench 240 of the thermal exchange cavity 200 may be formed from an array of trenches, pillars, channels, grooves or other geometric structures. In an embodiment, as illustrated in FIG. 9D, the trench 240 may contain regions including a plurality of microstructures or protrusions surrounding the periphery of the trench 240 to increase the surface area and thereby the thermal capacity of the cooling structure 20.

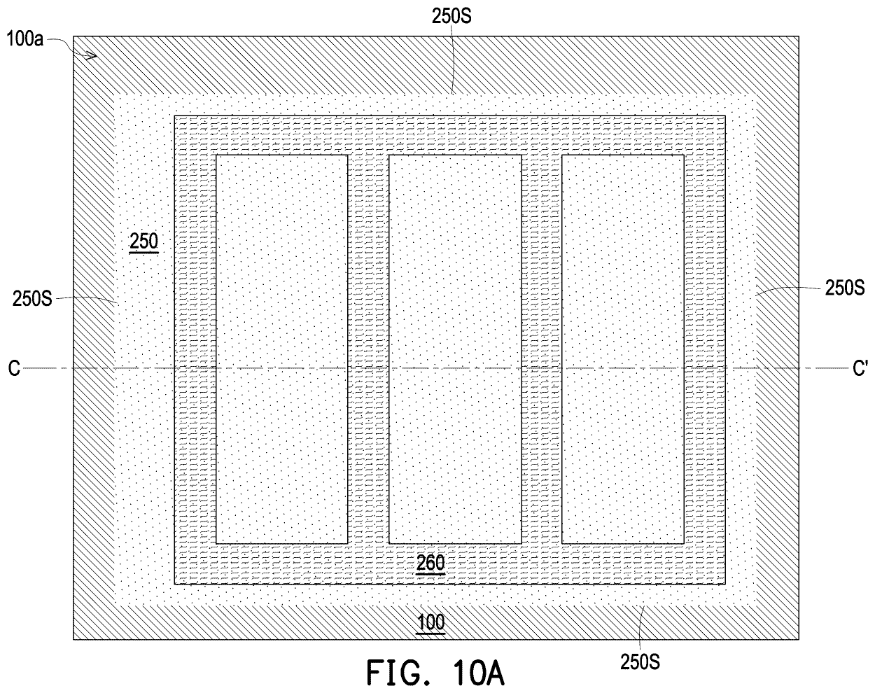

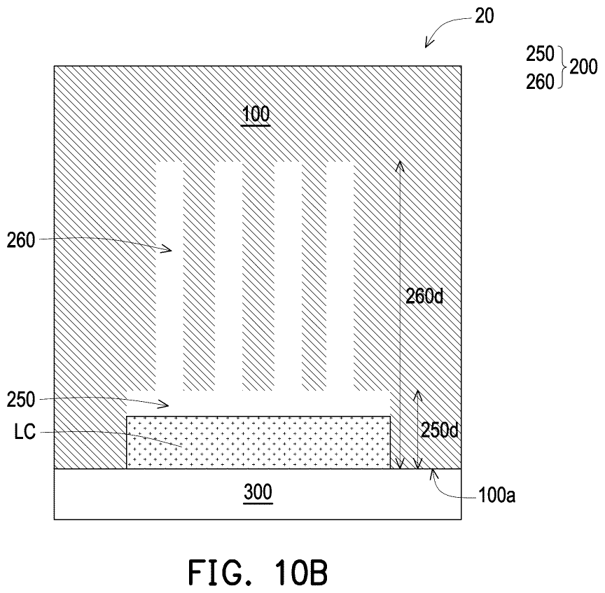

FIG. 10A illustrates a top view of a portion of a cooling structure 20, including a substrate 100 and a thermal exchange cavity 200 formed therein, as examples of possible configuration of the thermal exchange cavity 200 including a first trench 250 and a second trench 260, according to some embodiments of the present disclosure. FIG. 10B is a cross-sectional view taken alone line C-C′ depicted in the top view of FIG. 10A.

As illustrated in FIG. 10A, in some embodiments, the second trench 260 may be formed as an interconnected structure comprising a plurality of linear trenches arranged along the vertical and horizontal axes of the first trench 250. In an embodiment, the second trench 260 may be positioned along lateral sidewalls 250S of the first trench 250. In another embodiment, one or more second trenches 260 may extend between opposite sides of the second trenches 260 formed along lateral sidewalls 250S of the first trench 250. In some embodiment, the plurality of second trenches 260 extending between opposite sides of the second trenches 260 formed along lateral sidewalls 250S of the first trench 250, may be a substantially uniform dimension and spaced substantially equidistant from each other, however, the disclosure is not limited thereto. In another embodiment, the second trenches 260 may be spaced at different distances, or non-equidistant on the first trench 250. In some embodiment, the width of the second trench 260 is smaller than the width of the first trench 250. In some embodiments, the width of the first trench 250 and second trench 260 may be independently of each other. The configuration shown in FIG. 10A merely serves as an exemplary illustration and the disclosure is not limited thereto. The width and depth of the first trench 250 and the second trench 260 may be adjusted according to design or performance requirements. In some embodiment, a pattern density of the first trench 250 over the substrate 100 is approximately 10 to 90 percent of the total surface area of the substrate 100, preferably 20 to 80 percent, and more preferably 40 to 60 percent. The pattern density of the first trench 250 is defined by the total area of the first trench 250 located within the substrate 100, divided by the total area of the substrate 100. In some embodiment, a pattern density of the second trench 260 over the first trench 250 is approximately 10 to 90 percent of the total surface area of the first trench 250, preferably 20 to 80 percent, and more preferably 40 to 60 percent. The pattern density of the second trench 260 is defined by the total area of the second trench 260 located within the first trench 250, divided by the total area of the first trench 250.

Referring to FIG. 10B, the thermal exchange cavity 200 may include a first trench 250 and a second trench 260. The second trench 260 may be in communication with the first trench 250. In some embodiments, the first trench 250 has a first depth 250d relative to the first surface 100a of the first substrate 100, and the second trench 260 has a second depth relative to the first surface 100a of the first substrate 100. In some embodiments, the second depth 260d of the second trench 260 is substantially greater than the first depth 250d of the first trench 250. In some embodiments, the first depth 250d of the first trench and the second depth 260d of the second trench may be independently of each other, in the range between 80 μm to 500 μm.

Through the integration of a thermal dissipation structure (i.e., thermal exchange cavity 200) in a substrate carrier (i.e., substrate 100), the thermal dissipation structure is proximate to the heat source, for example a SoIC die. Therefore, better thermal dissipation property of the IC can be achieved, which greatly improve the power efficiency, performance and reliability of the IC.

In accordance with some embodiments of the disclosure, a structure including a semiconductor component, a cooling structure disposed on the semiconductor component, and a capping layer disposed between the cooling structure and the semiconductor component is provided. The cooling structure includes a first substrate, a second substrate and a liquid coolant. The first substrate is disposed between the second substrate and the semiconductor component. The first substrate incudes a thermal exchange cavity. The liquid coolant is distributed in the thermal exchange cavity of the first substrate. The capping layer includes a wetting region covered by the liquid coolant. The semiconductor component includes a first semiconductor die and a second semiconductor die. The first semiconductor die is electrically connected to the second semiconductor die. The first semiconductor die is located between the second semiconductor die and the cooling structure. The liquid coolant is distributed in a bottom region of the thermal exchange cavity. The liquid coolant is in contact with the wetting region of the capping layer. The thermal exchange cavity further includes an upper region located above the bottom region. The upper region of the thermal exchange cavity is not occupied by the liquid coolant. The upper region of the thermal exchange cavity is spaced apart from the wetting region of the capping layer. A thermal interface material layer disposed between the first substrate and the second substrate. The second substrate comprises a thermal conductive lid. The thermal exchange cavity comprises a trench extending partially through the first substrate, from a first surface of the first substrate towards a second surface of the first substrate. The thermal exchange cavity includes a trench and a via, extending partially through the first substrate, from a first surface of the first substrate towards a second surface of the first substrate. The trench is in communication with the via. The thermal exchange cavity includes a first trench and a second trench in communicated with the first trench. The first trench has a first depth relative to a first surface of the first substrate. The second trench has a second depth relative to the first surface of the first substrate. The second depth of the second trench is substantially greater than the first depth of the first trench.

In accordance with some embodiments of the disclosure, a structure including a first substrate, a second substrate disposed on the first substrate, and an interface layer interposed between the first substrate and the second substrate is provided. The second substrate includes a thermal dissipation structure for receiving a thermal conductive material. The thermal dissipation structure includes a base portion and an elongated portion. A first side of the base portion is disposed on and substantially levelled with a first surface of the first substrate. The elongated portion extends from a second side of the base portion in a direction substantially perpendicular to the second side of the base portion. The interface layer having a hydrophilic surface in contact with the thermal conductive material. A third substrate disposed on a second surface of the second substrate, and in contact with the elongated portion of the thermal dissipation structure penetrating through the second substrate. A height of the second substrate is greater than a height of the thermal dissipation structure. A top surface of the elongated portion is lower than a second surface of the second substrate. The second surface of the second substrate is opposite to the first surface of the second substrate. The thermal dissipation structure further includes a top portion disposed on the elongated portion. The top portion and the base portion are at opposing sides of the elongated portion of the thermal dissipation structure. A top surface of the top portion is substantially levelled with the second surface of the second substrate. A third substrate is disposed on the second substrate. The third substrate covering the underlying top portion of the thermal dissipation structure.

In accordance with some alternative embodiments of the disclosure, a method including providing a first substrate, depositing a capping layer on a first surface of the first substrate, and attaching a semiconductor component to the capping layer is provided. The semiconductor component and first substrate are located at opposing sides of the capping layer. The method includes providing a second substrate including a thermal conductive lid, and adhering the second substrate to a second surface of the first substrate through a thermal interface material layer. The method includes performing a patterning process on the first surface of the first substrate to form a thermal exchange cavity extending partially from the first surface of the first substrate towards the second surface of the first substrate. The method includes performing a first surface treatment to form a non-wetting region conforming to at least a portion of inner sidewalls of the thermal exchange cavity. The first surface treatment to form the non-wetting region includes exposing the inner sidewalls of the thermal exchange cavity to plasma treatment with a reactant gas. The reactant gas is at least one selected from the group consisting of hexamethyldisiloxane, octafluorocyclobutane, or tetrafluoromethane. The method further includes performing a second surface treatment on the capping layer to form a wetting region on a side of the capping layer deposited on the first substrate. The second surface treatment includes coupling a surface-treating agent having a polar functional group on the side of the capping layer facing the first substrate. The method further includes delivering a liquid coolant into the thermal exchange cavity. The liquid coolant is deposited in a region of the thermal exchange cavity directly over the wetting region of the capping layer. The method further includes performing a thinning process to remove a portion of the first substrate through the second surface of the first substrate to reveal the underlying thermal exchange cavity. The thinning process includes back-grinding, chemical mechanical polishing (CMP), or etching. The thinning process is performed before filling the thermal exchange cavity with the liquid coolant.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A structure, comprising:
a semiconductor component;
a cooling structure disposed on the semiconductor component, the cooling structure comprising a first substrate, a second substrate and a liquid coolant, wherein the first substrate is disposed between the second substrate and the semiconductor component, the first substrate comprises a thermal exchange cavity, and the liquid coolant is distributed in the thermal exchange cavity of the first substrate; and
a capping layer disposed between the cooling structure and the semiconductor component, the capping layer comprising a wetting region covered by the liquid coolant.

2. The structure of claim 1, wherein the semiconductor component comprises a first semiconductor die and a second semiconductor die, the first semiconductor die is electrically connected to the second semiconductor die, and the first semiconductor die is located between the second semiconductor die and the cooling structure.

3. The structure of claim 1, wherein the liquid coolant is distributed in a bottom region of the thermal exchange cavity, and the liquid coolant is in contact with the wetting region of the capping layer.

4. The structure of claim 3, wherein the thermal exchange cavity further comprises an upper region located above the bottom region, and the upper region of the thermal exchange cavity is not occupied by the liquid coolant.

5. The structure of claim 4, wherein the upper region of the thermal exchange cavity is spaced apart from the wetting region of the capping layer.

6. The structure of claim 1 further comprising a thermal interface material layer disposed between the first substrate and the second substrate, wherein the second substrate comprises a thermal conductive lid.

7. The structure of claim 1, wherein the thermal exchange cavity comprises a trench extending partially through the first substrate, from a first surface of the first substrate towards a second surface of the first substrate.

8. The structure of claim 1, wherein the thermal exchange cavity comprises a trench and a via, extending partially through the first substrate, from a first surface of the first substrate towards a second surface of the first substrate, and the trench is in communication with the via.

9. The structure of claim 1, wherein the thermal exchange cavity comprises a first trench and a second trench in communicated with the first trench, the first trench has a first depth relative to a first surface of the first substrate, and the second trench has a second depth relative to the first surface of the first substrate, and the second depth of the second trench is substantially greater than the first depth of the first trench.

10. A structure, comprising:
a first substrate;
a second substrate disposed on the first substrate, the second substrate comprising a thermal dissipation structure to receive a thermal conductive material, wherein the thermal dissipation structure comprises a base portion and an elongated portion, wherein a first side of the base portion is disposed on and substantially levelled with a first surface of the second substrate, and the elongated portion extends from a second side of the base portion in a direction substantially perpendicular to the second side of the base portion; and
an interface layer interposed between the first substrate and the second substrate, wherein the interface layer having a hydrophilic surface in contact with the thermal conductive material.

11. The structure of claim 10 further comprising a third substrate disposed on a second surface of the second substrate, and in contact with the elongated portion of the thermal dissipation structure penetrating through the second substrate.

12. The structure of claim 10, wherein a height of the second substrate is greater than a height of the thermal dissipation structure, such that a top surface of the elongated portion is lower than a second surface of the second substrate, wherein the second surface of the second substrate is opposite to the first surface of the second substrate.

13. The structure of claim 12, wherein the thermal dissipation structure further comprises:
a top portion disposed on the elongated portion, the top portion and the base portion are at opposing sides of the elongated portion of the thermal dissipation structure, and a top surface of the top portion is substantially levelled with the second surface of the second substrate; and
a third substrate is disposed on the second substrate, the third substrate covering the underlying top portion of the thermal dissipation structure.

14. A method, comprising:
providing a first substrate;
depositing a capping layer on a first surface of the first substrate;
attaching a semiconductor component to the capping layer, wherein the semiconductor component and first substrate are located at opposing sides of the capping layer;
providing a second substrate comprising a thermal conductive lid; and
adhering the second substrate to a second surface of the first substrate through a thermal interface material layer.

15. The method of claim 14, further comprising:
performing a patterning process on the first surface of the first substrate to form a thermal exchange cavity extending partially from the first surface of the first substrate towards the second surface of the first substrate, and
performing a first surface treatment to form a non-wetting region conforming to at least a portion of inner sidewalls of the thermal exchange cavity.

16. The method of claim 15, wherein the first surface treatment to form the non-wetting region comprises exposing the inner sidewalls of the thermal exchange cavity to plasma treatment with a reactant gas, wherein the reactant gas is at least one selected from the group consisting of hexamethyldisiloxane, octafluorocyclobutane, or tetrafluoromethane.

17. The method of claim 15, further comprising:
performing a second surface treatment on the capping layer to form a wetting region on a side of the capping layer disposed on the first substrate.

18. The method of claim 17, wherein the second surface treatment comprising coupling a surface-treating agent having a polar functional group on the side of the capping layer facing the first substrate.

19. The method of claim 17, further comprising:
delivering a liquid coolant into the thermal exchange cavity, wherein the liquid coolant is deposited in a region of the thermal exchange cavity directly over the wetting region of the capping layer.

20. The method of claim 19, further comprising:
performing a thinning process to remove a portion of the first substrate through the second surface of the first substrate to reveal the underlying thermal exchange cavity, wherein the thinning process comprises back-grinding, chemical mechanical polishing, or etching, and the thinning process is performed before filling the thermal exchange cavity with the liquid coolant.
